(19) United States
(12) Patent Application Publication
(10) Pub. No.: US 2023/0207630 A1
(43) Pub. Date: Jun. 29, 2023

(54) SEMICONDUCTOR DEVICE

(71) Applicant: SONY SEMICONDUCTOR SOLUTIONS CORPORATION, KANAGAWA (JP)

(72) Inventor: KENICHI OOKUBO, KANAGAWA (JP)

(21) Appl. No.: 17/999,393

(22) PCT Filed: Apr. 19, 2021
(86) PCT No.: PCT/JP2021/015887

§ 371 Date: Nov. 21, 2022

(30) Foreign Application Priority Data
May 29, 2020 (JP) 2020-094350

(51) Int. Cl. H01L 29/08; H01L 29/78; H01L 29/66

(52) U.S. Cl. CPC H01L 29/0878; H01L 29/785; H01L 29/66795

(57) ABSTRACT

Provided is a semiconductor device capable of increasing the breakdown voltage of a field effect transistor while suppressing an increase in the number of processes. The semiconductor device includes a semiconductor substrate and a field effect transistor provided on a first main surface side of the semiconductor substrate. The field effect transistor includes a semiconductor region where a channel is formed, a source region of a first conductivity type located on one side in a gate length direction of the semiconductor region, a drain region of the first conductivity type located on the other side in the gate length direction, and a drain electrode connected to the drain region. The drain region includes a structure in which a first high-concentration layer having a high impurity concentration of the first conductivity type, a low-concentration layer having a low impurity concentration of the first conductivity type, and a second high-concentration layer having a high impurity concentration of the first conductivity type are connected in this order from the semiconductor region to the drain electrode side.

### TECHNICAL FIELD

The present disclosure relates to a semiconductor device.

### BACKGROUND ART

In the related art, a fin high-breakdown-voltage field effect transistor has been known (See, for example, Patent Documents 1 and 2).

### CITATION LIST

### Patent Document

### Patent Document 1: Japanese Patent Application Laid-Open No. 2018-73971

### Patent Document 2: Japanese Patent Application Laid-Open No. 2013-143437

### SUMMARY OF THE INVENTION

### Problems to be Solved by the Invention

In the high-breakdown-voltage field effect transistor, since it is necessary to create an electric field relaxation structure and a breakdown voltage structure, the number of manufacturing processes is large, and also, the element area tends to be large.

The present disclosure has been made in view of such circumstances, and an object of the present disclosure is to provide a semiconductor device capable of increasing the breakdown voltage of a field effect transistor while suppressing an increase in the number of processes.

### Solutions to Problems

A semiconductor device according to an aspect of the present disclosure includes a semiconductor substrate, and a field effect transistor provided on a first main surface side of the semiconductor substrate. The field effect transistor includes a semiconductor region in which a channel is formed, a source region of a first conductivity type, the source region being located on one side in a gate length direction of the semiconductor region, a drain region of the first conductivity type, the drain region being located on another side in the gate length direction, and a drain electrode connected to the drain region. The drain region includes a structure in which a first high-concentration layer having a high impurity concentration of the first conductivity type, a low-concentration layer having a low impurity concentration of the first conductivity type, and a second high-concentration layer having a high impurity concentration of the first conductivity type are connected in this order from the semiconductor region to the drain electrode side.

With this configuration, the low-concentration layer in the drain region can include, for example, a part of the well diffusion layer. Furthermore, providing the low-concentration layer can increase the resistance of the drain region, and can increase the breakdown voltage between the source and the drain. Therefore, a semiconductor device capable of increasing the breakdown voltage of the field effect transistor while suppressing an increase in the number of processes can be provided.

### BRIEF DESCRIPTION OF DRAWINGS

FIG. 1A is a plan view illustrating Configuration Example 1 of a semiconductor device according to an embodiment of the present disclosure.

FIG. 1B is a sectional view illustrating Configuration Example 1 of the semiconductor device according to the embodiment of the present disclosure.

FIG. 1C is a sectional view illustrating Configuration Example 1 of the semiconductor device according to the embodiment of the present disclosure.

FIG. 2 is a sectional view illustrating Configuration Example 2 of the semiconductor device according to the embodiment of the present disclosure.

FIG. 3A is a plan view illustrating a method for manufacturing the semiconductor device according to the embodiment of the present disclosure in process order.

FIG. 3B is a sectional view illustrating the method for manufacturing the semiconductor device according to the embodiment of the present disclosure in process order.

FIG. 3C is a sectional view illustrating the method for manufacturing the semiconductor device according to the embodiment of the present disclosure in process order.

FIG. 4A is a plan view illustrating the method for manufacturing the semiconductor device according to the embodiment of the present disclosure in process order.

FIG. 4B is a sectional view illustrating the method for manufacturing the semiconductor device according to the embodiment of the present disclosure in process order.

FIG. 4C is a sectional view illustrating the method for manufacturing the semiconductor device according to the embodiment of the present disclosure in process order.

FIG. 5A is a plan view illustrating the method for manufacturing the semiconductor device according to the embodiment of the present disclosure in process order.

FIG. 5B is a sectional view illustrating the method for manufacturing the semiconductor device according to the embodiment of the present disclosure in process order.

FIG. 5C is a sectional view illustrating the method for manufacturing the semiconductor device according to the embodiment of the present disclosure in process order.

FIG. 6A is a plan view illustrating the method for manufacturing the semiconductor device according to the embodiment of the present disclosure in process order.

FIG. 6B is a sectional view illustrating the method for manufacturing the semiconductor device according to the embodiment of the present disclosure in process order.

FIG. 6C is a sectional view illustrating the method for manufacturing the semiconductor device according to the embodiment of the present disclosure in process order.

FIG. 7A is a plan view illustrating the method for manufacturing the semiconductor device according to the embodiment of the present disclosure in process order.

FIG. 7B is a sectional view illustrating the method for manufacturing the semiconductor device according to the embodiment of the present disclosure in process order.

FIG. 7C is a sectional view illustrating the method for manufacturing the semiconductor device according to the embodiment of the present disclosure in process order.

FIG. 8A is a plan view illustrating the method for manufacturing the semiconductor device according to the embodiment of the present disclosure in process order.

FIG. 8B is a sectional view illustrating the method for manufacturing the semiconductor device according to the embodiment of the present disclosure in process order.

FIG. 8C is a sectional view illustrating the method for manufacturing the semiconductor device according to the embodiment of the present disclosure in process order.

FIG. 9A is a plan view illustrating the method for manufacturing the semiconductor device according to the embodiment of the present disclosure in process order.

FIG. 9B is a sectional view illustrating the method for manufacturing the semiconductor device according to the embodiment of the present disclosure in process order.

FIG. 9C is a sectional view illustrating the method for manufacturing the semiconductor device according to the embodiment of the present disclosure in process order.

FIG. 10A is a plan view illustrating the method for manufacturing the semiconductor device according to the embodiment of the present disclosure in process order.

FIG. 10B is a sectional view illustrating the method for manufacturing the semiconductor device according to the embodiment of the present disclosure in process order.

FIG. 10C is a sectional view illustrating the method for manufacturing the semiconductor device according to the embodiment of the present disclosure in process order.

FIG. 11A is a plan view illustrating the method for manufacturing the semiconductor device according to the embodiment of the present disclosure in process order.

FIG. 11B is a sectional view illustrating the method for manufacturing the semiconductor device according to the embodiment of the present disclosure in process order.

FIG. 11C is a sectional view illustrating the method for manufacturing the semiconductor device according to the embodiment of the present disclosure in process order.

FIG. 12A is a plan view illustrating the method for manufacturing the semiconductor device according to the embodiment of the present disclosure in process order.

FIG. 12B is a sectional view illustrating the method for manufacturing the semiconductor device according to the embodiment of the present disclosure in process order.

FIG. 12C is a sectional view illustrating the method for manufacturing the semiconductor device according to the embodiment of the present disclosure in process order.

FIG. 13A is a plan view illustrating the method for manufacturing the semiconductor device according to the embodiment of the present disclosure in process order.

FIG. 13B is a sectional view illustrating the method for manufacturing the semiconductor device according to the embodiment of the present disclosure in process order.

FIG. 13C is a sectional view illustrating the method for manufacturing the semiconductor device according to the embodiment of the present disclosure in process order.

FIG. 14A is a plan view illustrating the method for manufacturing the semiconductor device according to the embodiment of the present disclosure in process order.

FIG. 14B is a sectional view illustrating the method for manufacturing the semiconductor device according to the embodiment of the present disclosure in process order.

FIG. 14C is a sectional view illustrating the method for manufacturing the semiconductor device according to the embodiment of the present disclosure in process order.

FIG. 15A is a plan view illustrating the method for manufacturing the semiconductor device according to the embodiment of the present disclosure in process order.

FIG. 15B is a sectional view illustrating the method for manufacturing the semiconductor device according to the embodiment of the present disclosure in process order.

FIG. 15C is a sectional view illustrating the method for manufacturing the semiconductor device according to the embodiment of the present disclosure in process order.

FIG. 16A is a plan view illustrating the method for manufacturing the semiconductor device according to the embodiment of the present disclosure in process order.

FIG. 16B is a sectional view illustrating the method for manufacturing the semiconductor device according to the embodiment of the present disclosure in process order.

FIG. 16C is a sectional view illustrating the method for manufacturing the semiconductor device according to the embodiment of the present disclosure in process order.

FIG. 17 is a sectional view illustrating Modification Example 1 of the semiconductor device according to the embodiment of the present disclosure.

FIG. 18 is a sectional view illustrating Modification Example 2 of the semiconductor device according to the embodiment of the present disclosure.

FIG. 19 is a sectional view illustrating Modification Example 3 of the semiconductor device according to the embodiment of the present disclosure.

FIG. 20 is a sectional view illustrating Modification Example 4 of the semiconductor device according to the embodiment of the present disclosure.

FIG. 21 is a sectional view illustrating Modification Example 5 of the semiconductor device according to the embodiment of the present disclosure.

### MODE FOR CARRYING OUT THE INVENTION

Hereinafter, embodiments of the present disclosure will be described with reference to the drawings. In the description of the drawings referred to in the following description, the same or similar parts are designated by the same or similar signs. However, it should be noted that the drawings are schematic, and the relationship between the thickness and the plane dimension, the ratio of the thickness of each layer, and the like are different from the actual ones. Therefore, the specific thicknesses and dimensions should be determined in consideration of the following description. Furthermore, it goes without saying that parts for which the dimensional relationship therebetween and the ratio thereof are different among the drawings.

The definition of directions such as up and down in the following description is merely for convenience of explanation, and does not limit the technical idea of the present disclosure. For example, where the object is rotated by 90° and observed, the top and bottom are read as converted to left and right, and where the object is rotated by 180° and observed, the top and bottom are read as reversed.

Furthermore, the following description includes a case where a direction is described using the terms X-axis direction, Y-axis direction, and Z-axis direction. For example, the X-axis direction and the Y-axis direction are directions that are parallel to a front surface 2a of a semiconductor substrate 2. The X-axis direction is also the gate length direction of MOS transistors 10 to 10F. The X-axis direction and the Y-axis direction are also referred to as horizontal directions. The Z-axis direction is a direction vertically intersecting the front surface 2a of the semiconductor substrate 2. The X-axis direction, the Y-axis direction, and the Z-axis direction are orthogonal to one another.

Furthermore, in the following description, a case where a first conductivity type is an N-type and a second conductivity type is a P-type will be exemplarily described. In the drawings, “+” added to “P” or “N” indicating a conductivity type means a semiconductor region having a relatively higher impurity concentration than a semiconductor region in which “+” is not added. “−” added to “P” or “N” means a semiconductor region having a relatively lower impurity concentration than a semiconductor region in which “−” is not added. However, the semiconductor regions denoted with the same “N” and “N” do not mean that the impurity concentrations of the respective semiconductor regions are exactly the same.

### Configuration Example 1

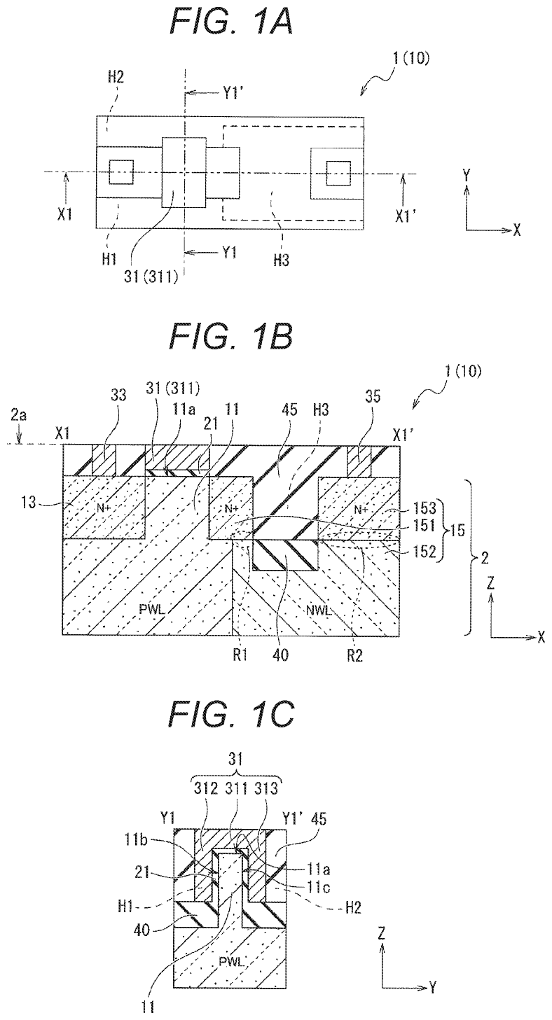

FIG. 1A is a plan view illustrating Configuration Example 1 of a semiconductor device 1 according to an embodiment of the present disclosure. FIGS. 1B and 1C are sectional views illustrating Configuration Example 1 of the semiconductor device 1 according to the embodiment of the present disclosure. FIG. 1B illustrates a section of the plan view illustrated in FIG. 1A taken along line X1-X1′. FIG. 1B illustrates a section of the plan view illustrated in FIG. 1A taken along line Y1-Y1′. Note that, FIG. 1A omits the illustration of an interlayer insulating film 45 in order to facilitate understanding of the structure using the flat paper.

As illustrated in FIGS. 1A to 1C, the semiconductor device 1 according to the embodiment includes the semiconductor substrate 2 and the metal oxide semiconductor (MOS) transistor 10 (an example of a “field effect transistor” of the present disclosure) of the first conductivity type (for example, N-type) provided at the semiconductor substrate 2. The semiconductor substrate 2 includes, for example, single-crystal silicon. The semiconductor substrate 2 includes the front surface 2a (an example of a “first main surface” of the present disclosure) and a back surface located on an opposite side of the front surface 2a. The MOS transistor 10 is provided on the front surface 2a side of the semiconductor substrate 2.

Furthermore, the semiconductor device 1 includes a P-type well diffusion layer PWL provided at the semiconductor substrate 2, an N-type well diffusion layer NWL provided at the semiconductor substrate 2, and a shallow trench isolation (STI) layer 40 provided at the semiconductor substrate 2. Note that the STI layer 40 is an example of an “insulating isolation layer” in the present disclosure.

The MOS transistor 10 includes: a semiconductor region 11 of the second conductivity type (for example, P-type) in which a channel is formed; an N-type source region 13 located on one side in a gate length direction of the semiconductor region 11 (for example, in the X-axis direction); an N-type drain region 15 located on the other side in the gate length direction of the semiconductor region 11 (for example, the opposite side of the source region 13 with the semiconductor region 11 interposed therebetween); a gate electrode 31 covering the semiconductor region 11; a gate insulating film 21 arranged between the semiconductor region 11 and the gate electrode 31; a source electrode 33 connected to the source region 13; and a drain electrode 35 connected to the drain region 15.

The semiconductor region 11 is a part of the semiconductor substrate 2 and includes P-type single crystal silicon. For example, the semiconductor region 11 is formed by etching a part of the P-type well diffusion layer PWL from the front surface 2a side of the semiconductor substrate 2. The shape of the semiconductor region 11 is a fin shape.

As illustrated in FIG. 1B, a trench H1 is provided on one side of the semiconductor region 11, and a trench H2 is provided on the other side of the semiconductor region 11, in the Y-axis direction orthogonal to the X-axis direction that is the gate length direction of the MOS transistor 10. The STI layers 40 are provided at the bottoms of the trenches H1 and H2. The STI layer 40 includes, for example, an insulating film such as SiO₂.

The gate insulating film 21 is provided so as to cover an upper surface 11a, a first side surface 11b, and a second side surface 11c of the semiconductor region 11 having a fin shape. The upper surface 11a is a part of the front surface 2a of the semiconductor substrate 2 and is parallel to the horizontal direction (i.e., the X-axis direction and the Y-axis direction). The first side surface 11b is located on one side of the upper surface 11a in the Y-axis direction. The second side surface 11c is located on the other side of the upper surface 11a in the Y-axis direction. The gate insulating film 21 includes, for example, a silicon oxide film (SiO₂ film).

The gate electrode 31 covers the semiconductor region 11 with the gate insulating film 21 interposed therebetween. For example, the gate electrode 31 includes a first part 311 facing the upper surface 11a of the semiconductor region 11 across the gate insulating film 21, a second part 312 facing the first side surface 11b of the semiconductor region 11 across the gate insulating film 21, and a third part 313 facing the second side surface 11c of the semiconductor region 11 across the gate insulating film 21. The second part 312 and the third part 313 are each connected to the lower surface of the first part 311. The second part 312 is arranged in the trench H1, and the third part 313 is arranged in the trench H2. The semiconductor region 11 is sandwiched between the second part 312 and the third part 313 of the gate electrode 31 in the Y-axis direction.

With this arrangement, the gate electrode 31 can simultaneously apply a gate voltage to the upper surface 11a, the first side surface 11b, and the second side surface 11c of the semiconductor region 11. That is, the gate electrode 31 can simultaneously apply a gate voltage to the semiconductor region 11 from a total of three directions including the upper side and both the left and right sides. Therefore, the gate electrode 31 can completely deplete the semiconductor region 11. The gate electrode 31 includes, for example, metal such as tungsten (W). Alternatively, the gate electrode 31 may include a polysilicon (Poly-Si) film doped with impurities.

The MOS transistor 10 may be referred to as a MOS transistor having a recessed gate structure, associated with a shape in which the second part 312 and the third part 313 of the gate electrode 31 are arranged in the trenches H1 and H2. Alternatively, the MOS transistor 10 may be referred to as a fin field effect transistor (FinFET) since the semiconductor region 11 has a fin shape. Alternatively, the MOS transistor 10 may be referred to as a recessed FinFET, associated with the two shapes described above.

The source region 13 includes an N-type high-concentration layer. The source electrode 33 is provided on the source region 13. The source electrode 33 includes, for example, metal such as tungsten (W).

The drain region 15 includes an N-type first high-concentration layer 151, an N-type low-concentration layer 152, and an N-type second high-concentration layer 153. The N-type low-concentration layer 152 includes, for example, the N-type well diffusion layer NWL. The drain region 15 includes a structure in which the first high-concentration layer 151, the low-concentration layer 152, and the second high-concentration layer 153 are connected in this order from the semiconductor region 11 to the drain electrode 35 side.

For example, the drain region 15 includes a first connection region R1 in which the first high-concentration layer 151 and the low-concentration layer 152 are connected in the Z-axis direction that is the thickness direction of the semiconductor substrate 2, and a second connection region R2 in which the low-concentration layer 152 and the second high-concentration layer 153 are connected in the Z-axis direction. The first high-concentration layer 151, the low-concentration layer 152, and the second high-concentration layer 153 are connected in series in this order from the semiconductor region 11 to the drain electrode 35 side. The drain electrode 35 is provided on the second high-concentration layer 153. The drain electrode 35 includes, for example, metal such as tungsten (W).

A trench H3 is provided between the first high-concentration layer 151 and the second high-concentration layer 153. The trench H3 is provided from the front surface 2a of the semiconductor substrate 2 to the upper portion of the low-concentration layer 152 in the Z-axis direction. As described above, the STI layer 40 is provided at each bottom of the trenches H1 and H2 located on both sides of the semiconductor region 11 and of the trench H3. In the N-type MOS transistor 10, electrons serving as carriers flow from the first high-concentration layer 151 to the second high-concentration layer 153 through the low-concentration layer 152 under the STI layer 40. The current path of the drain current in the low-concentration layer 152 is extended in the Z-axis direction by the thickness of STI layer 40.

### Configuration Example 2

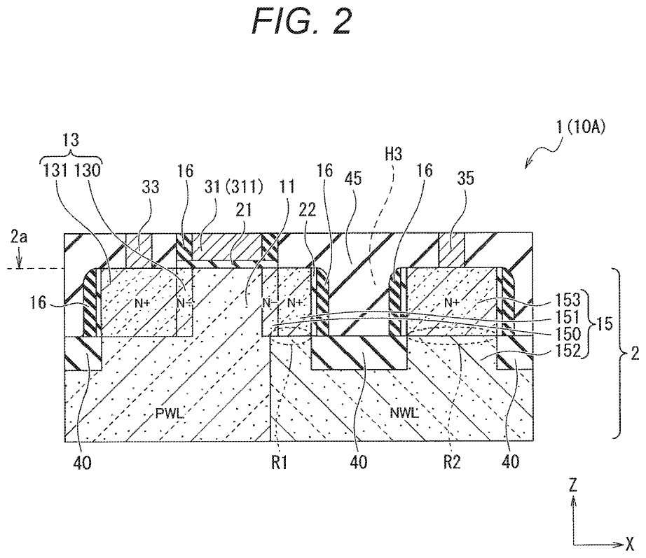

FIG. 2 is a sectional view illustrating Configuration Example 2 of the semiconductor device 1 according to the embodiment of the present disclosure. As illustrated in FIG. 2, the semiconductor device 1 according to the embodiment may include the MOS transistor 10A (an example of a “field effect transistor” of the present disclosure). In the MOS transistor 10A, main structural differences from the MOS transistor 10 illustrated in FIGS. 1A to 1C are that a source region and a drain region have an LDD structure, and that sidewalls are provided at a gate electrode and the like.

As illustrated in FIG. 2, the source region 13 of the MOS transistor 10A includes an N-type low-concentration layer 130 and an N-type high-concentration layer 131. The low-concentration layer 130 and the high-concentration layer 131 are connected in series in this order from the semiconductor region 11 to the source electrode 33 side. The source electrode 33 is provided on the high-concentration layer 131.

The drain region 15 of the MOS transistor 10A includes an N-type first low-concentration layer 150, the N-type first high-concentration layer 151, an N-type second low-concentration layer 152, and the N-type second high-concentration layer 153. The first low-concentration layer 150, the first high-concentration layer 151, the low-concentration layer 152, and the second high-concentration layer 153 are connected in this order from the semiconductor region 11 to the drain electrode 35 side. In this example, the second low-concentration layer 152 is an example of the “low-concentration layer” of the present disclosure. The second low-concentration layer 152 includes the N-type well diffusion layer NWL.

Note that FIG. 2 illustrates a case where the first low-concentration layer 150 is partially connected to the second low-concentration layer 152 in the Z-axis direction, but these are merely examples. The first low-concentration layer 150 may be connected to the second low-concentration layer 152 only via the first high-concentration layer. That is, the first low-concentration layer 150 may not be directly connected to the second low-concentration layer 152.

Sidewalls 16 are provided at the side surface of the source region 13, each side surface of the first high-concentration layer 151 and the second high-concentration layer 153 in the drain region 15, and the side surfaces of the first part 311 of the gate electrode 31. Note that FIG. 2 illustrates a case where an insulating film 22 is interposed between the sidewall 16 and each side surface described above, but the insulating film 22 may not be provided. The insulating film 22 is, for example, a SiO₂ film, and is a film formed simultaneously with the gate insulating film 21.

The STI layer 40 is provided not only on the second low-concentration layer 152 of the MOS transistor 10A but also around the MOS transistor 10A. The STI layer 40 provided around the MOS transistor 10A electrically isolates the MOS transistor 10A from other elements provided on the front surface 2a side of the semiconductor substrate 2. Examples of other elements include a transistor other than the MOS transistor 10A, a resistor, a capacitor, and the like. Other elements may be formed using a CMOS process, similarly to the MOS transistor 10A.

### Manufacturing Method

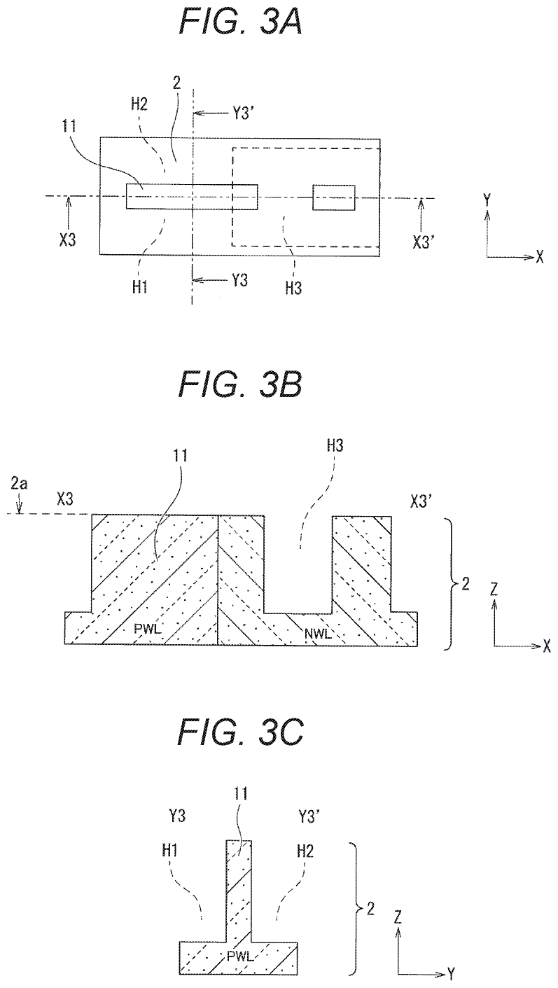

Next, a method for manufacturing the semiconductor device 1 according to the embodiment of the present disclosure will be described. FIGS. 3A to 16C are views illustrating the method for manufacturing the semiconductor device 1 according to the embodiment of the present disclosure in process order. In FIGS. 3A to 16C, Fig. nA (n is an integer of 3 or more and 16 or less) is a plan view, Fig. nB is a sectional view of Fig. nA taken along line Xn-Xn′, and Fig. nC is a sectional view of Fig. nA taken along line Yn-Yn′. Here, a method for manufacturing Configuration Example 2 illustrated in FIG. 2 will be described.

The semiconductor device 1 is manufactured using various apparatuses such as film forming apparatuses (including a chemical vapor deposition (CVD) apparatus, a thermal oxidation furnace, a sputtering apparatus, and a resist coating apparatus), an exposure apparatus, an ion implantation apparatus, an annealing apparatus, an etching apparatus, and a chemical mechanical polishing (CMP) apparatus. Hereinafter, these apparatuses are collectively referred to as a manufacturing apparatus.

In FIGS. 3A to 3C, the manufacturing apparatus forms the N-type well diffusion layer NWL and the P-type well diffusion layer PWL on the front surface 2a side of the semiconductor substrate 2. Next, the manufacturing apparatus partially etches the front surface 2a side of the semiconductor substrate 2. With this process, the manufacturing apparatus forms the trenches H1 to H3.

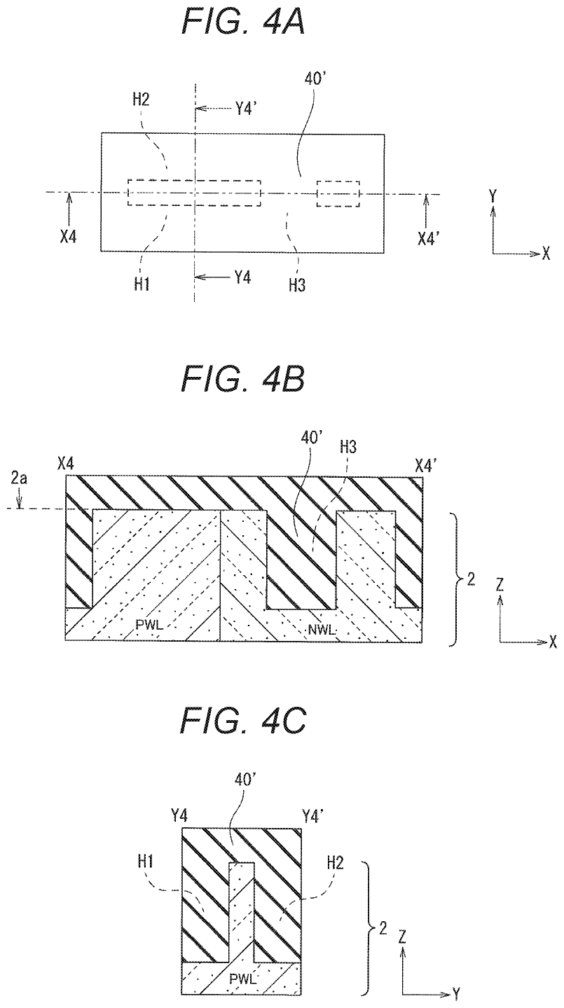

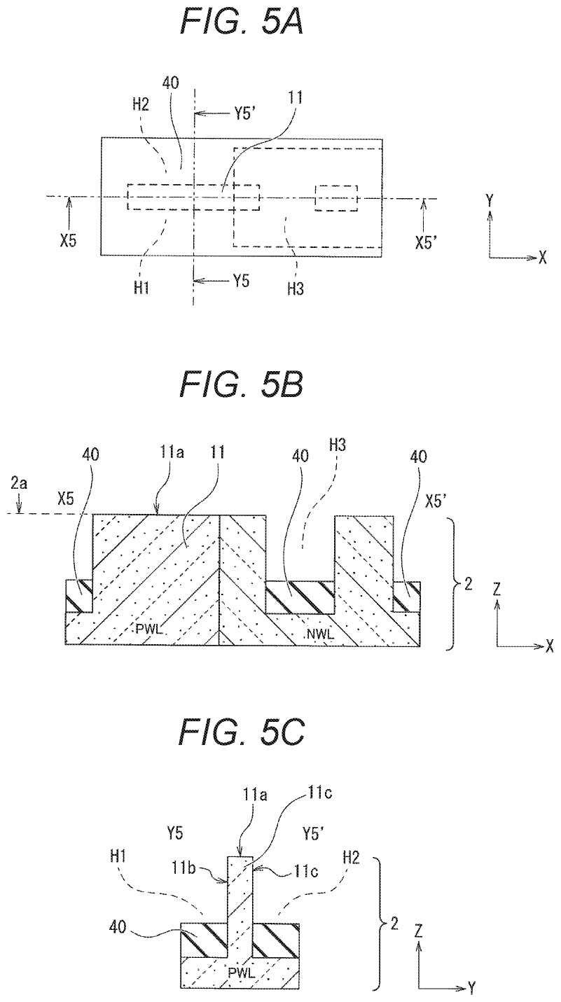

Next, as illustrated in FIGS. 4A to 4C, the manufacturing apparatus forms a SiO₂ film 40′ on the semiconductor substrate by using the CVD method, thereby filling the trenches H1 to H3. Next, the manufacturing apparatus performs CMP processing on the SiO₂ film 40′ to flatten the SiO₂ film 40′. Next, the manufacturing apparatus etches the SiO₂ film 40′. With this process, as illustrated in FIGS. 5A to 5C, the upper surface 11a, a part of the first side surface 11b, and a part of the second side surface 11c of the semiconductor region 11 are exposed from the SiO₂ film 40′. Furthermore, the STI layer 40 is formed from the SiO₂ film 40′ in the trenches H1 to H3.

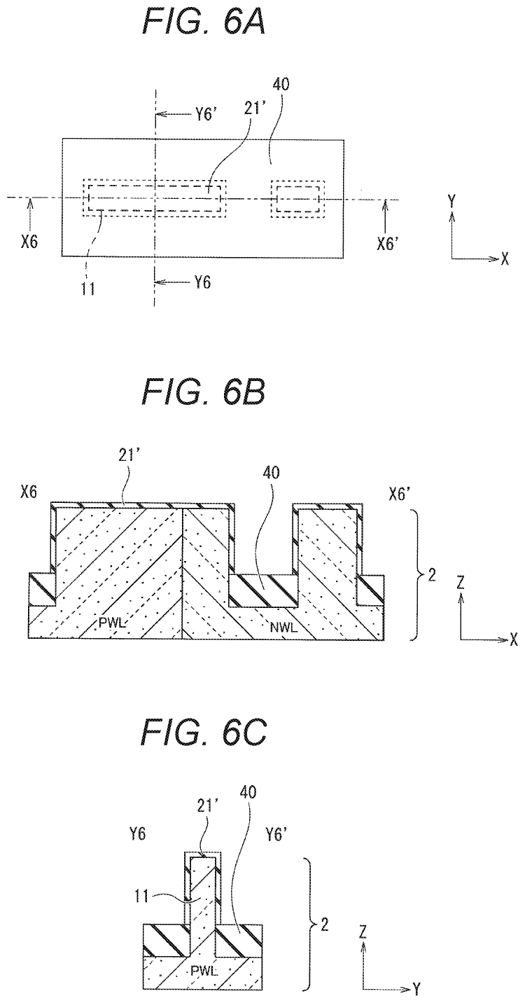

Next, the manufacturing apparatus thermally oxidizes the semiconductor substrate 2. With this process, as illustrated in FIGS. 6A to 6C, a gate insulating film 21′ is formed on each of the upper surface 11a, a part of the first side surface 11b, and a part of the second side surface 11c of the semiconductor region 11 exposed from the STI layer 40.

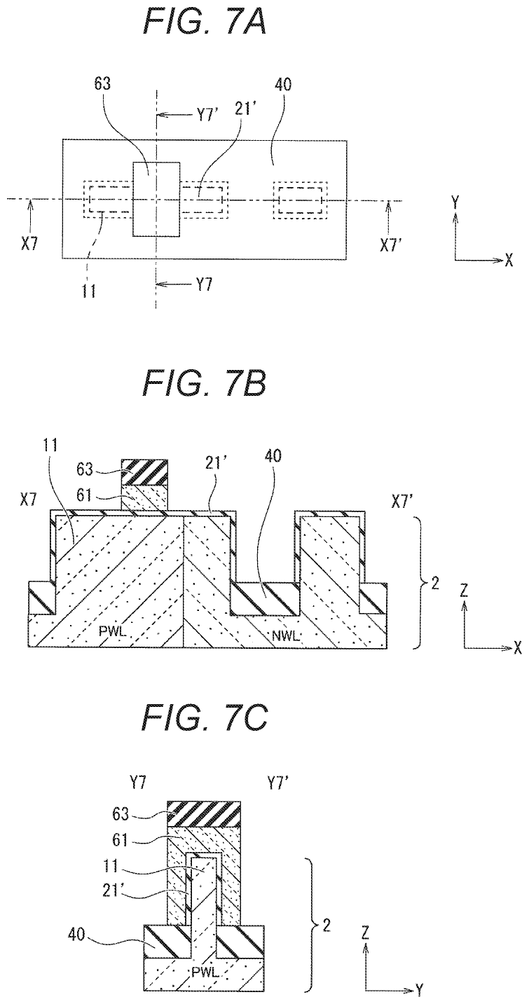

Next, the manufacturing apparatus forms a polysilicon (Poly-Si) film above the semiconductor substrate 2 by using a CVD method, thereby filling the trenches H1 to H3. Next, the manufacturing apparatus forms a silicon nitride film (SiN film) on the polysilicon film by using a CVD method. Next, the manufacturing apparatus forms a resist pattern (not illustrated) on the SiN film. The resist pattern has a shape in which a region where the gate electrode is to be formed is covered and other regions are open. Next, the manufacturing apparatus etches and removes the SiN film and the polysilicon film by using the resist pattern as a mask. In this etching, SiO₂ films such as the gate insulating film 21′ and the STI layer 40 are used as etching stopper layers. With this process, as illustrated in FIGS. 7A to 7C, a polysilicon film 61 and a SiN film 63 having the shape of the gate electrode are formed in the semiconductor region 11 with the gate insulating film 21′ interposed therebetween. Thereafter, the manufacturing apparatus removes the resist pattern.

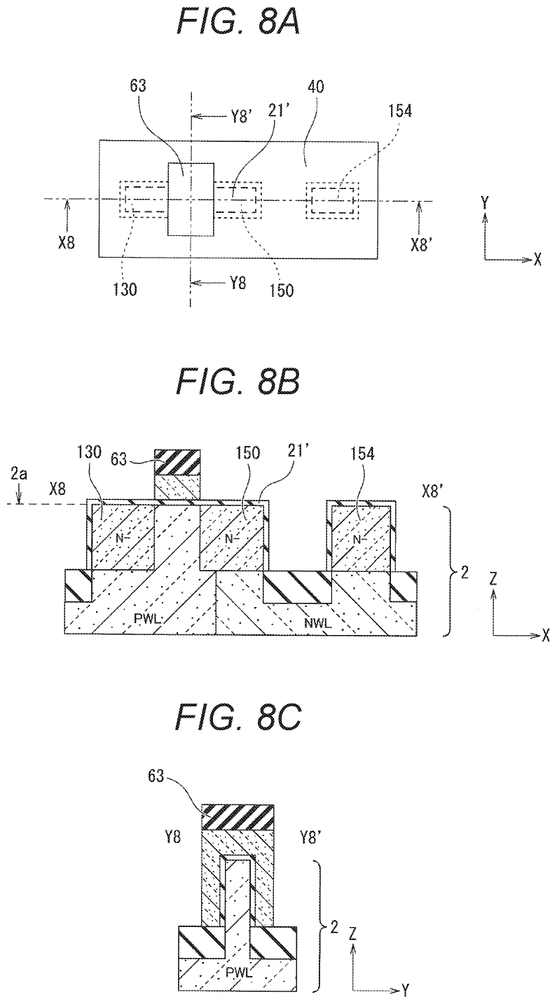

Next, the manufacturing apparatus ion-implants N-type impurities into the front surface 2a side of the semiconductor substrate 2 by using the SiN film 63 having the shape of the gate electrode as a mask. With this process, as illustrated in FIGS. 8A to 8C, the manufacturing apparatus forms the low-concentration layer 130 in the source region, and the first low-concentration layer 150 and a third low-concentration layer 154 in the drain region, on the front surface 2a side of the semiconductor substrate 2.

A channel region of the MOS transistor 10A is a region between the low-concentration layer 130 in the source region and the first low-concentration layer 150 in the drain region. The N-type low-concentration layers 130 and 150 that define the range of the channel region are formed by ion implantation using a SiN film having the shape of a gate electrode as a mask. Therefore, as compared with a case where the range of the channel region is defined by the N-type well diffusion layer, for example, the relative misalignment of the channel region with respect to the gate electrode can be reduced, and the channel length can be stabilized. This makes it possible to reduce characteristic variation of the MOS transistor.

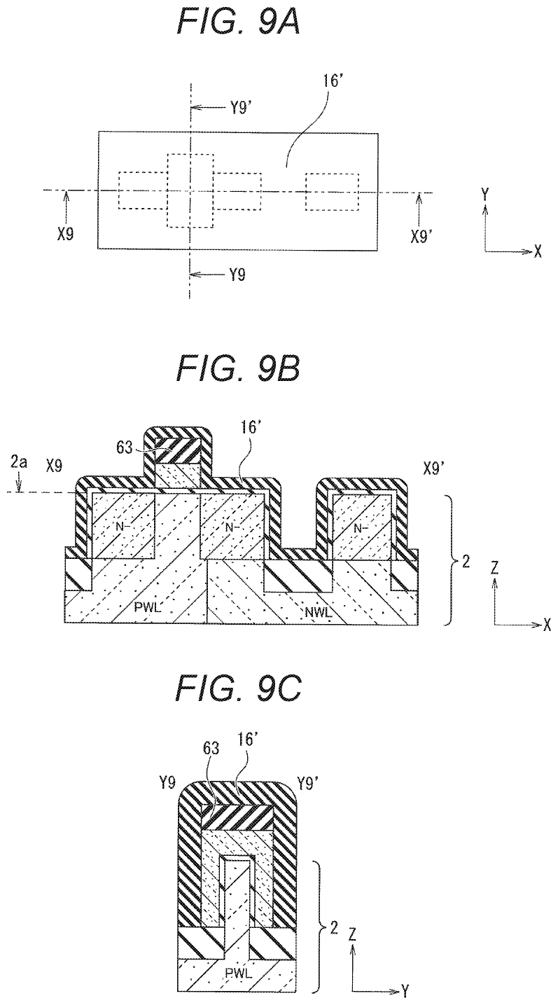

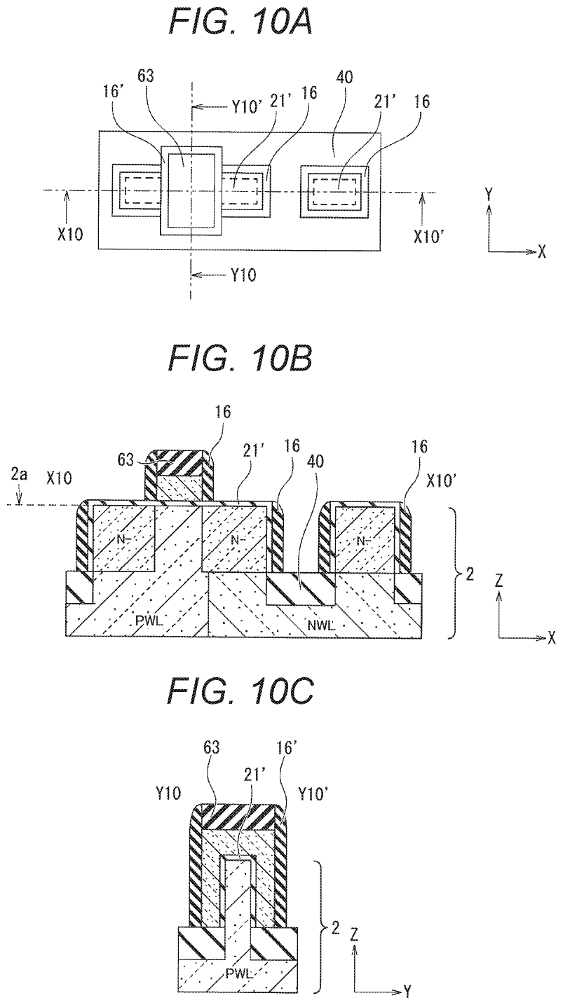

Next, as illustrated in FIGS. 9A to 9C, the manufacturing apparatus forms a SiN film 16′ above the semiconductor substrate 2. Next, the manufacturing apparatus etches back the SiN film 16′. With this process, as illustrated in FIGS. 10A to 10C, the manufacturing apparatus forms the sidewalls 16 from the SiN film 16′.

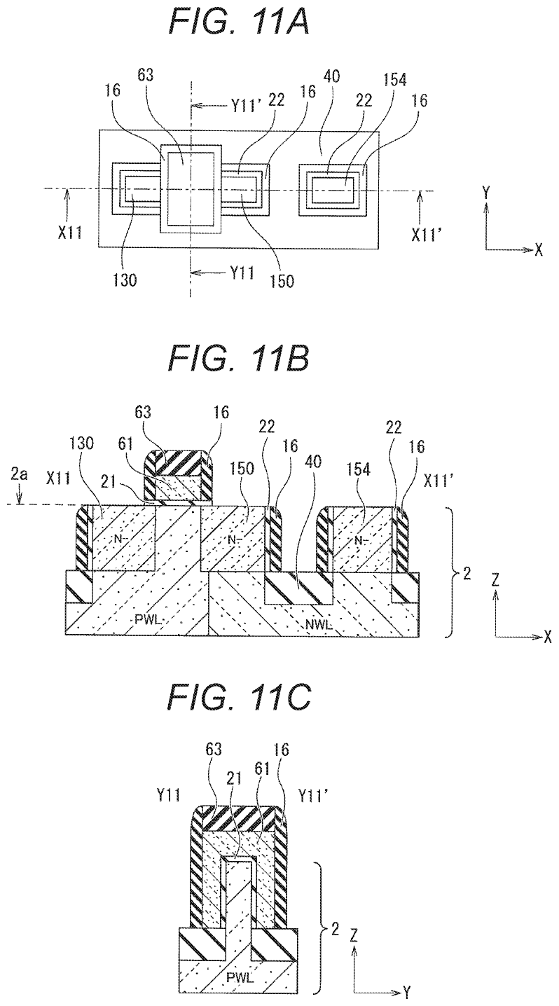

Next, as illustrated in FIGS. 11A to 11C, the manufacturing apparatus etches and removes the gate insulating film 21′ by using the SiN film 63 and the sidewall 16 as masks. With this process, each surface of the low-concentration layer 130, the first low-concentration layer 150, and the third low-concentration layer 154 are exposed from the gate insulating film 21′. The gate insulating film 21 that cover the channel region and the insulating film 22 are formed from the gate insulating film 21′. The insulating film 22 is the gate insulating film 21′ left between the low-concentration layer 130 and the sidewall 16, between the first low-concentration layer 150 and the sidewall 16, and between the third low-concentration layer 154 and the sidewalls 16.

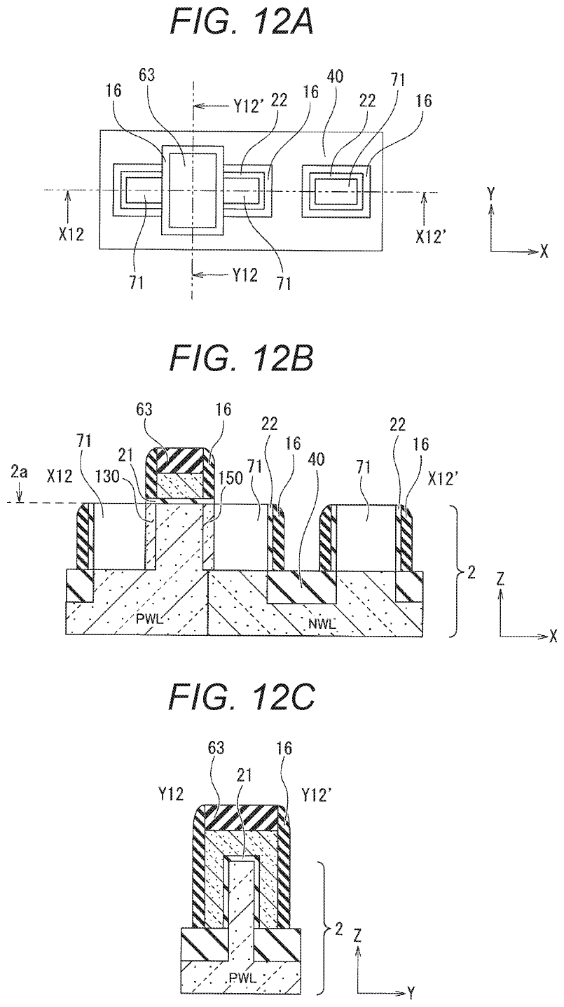

Next, as illustrated in FIGS. 12A to 12C, the manufacturing apparatus etches and removes a portion of the low-concentration layer 130 and the first low-concentration layer 150 exposed from the sidewall 16, and the third low-concentration layer 154, thereby forming recesses 71. The manufacturing apparatus performs etching until the P-type well diffusion layer PWL or the N-type well diffusion layer NWL is exposed on the bottom surface of the recess 71.

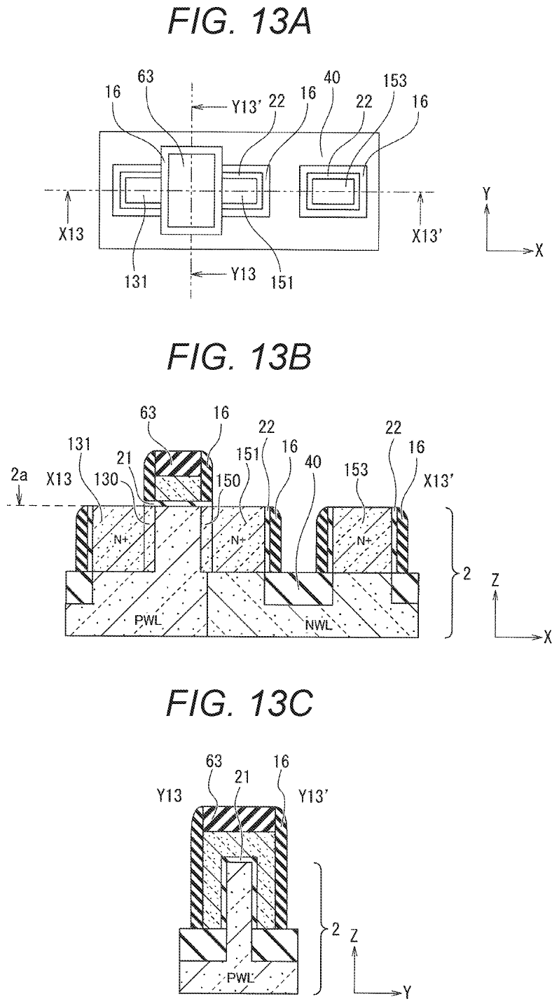

Next, the manufacturing apparatus allows silicon containing N-type impurities at a high concentration to selectively epitaxially grow on the semiconductor substrate 2. With this process, as illustrated in FIGS. 13A to 13C, the high-concentration layer 131 in the source region and the first high-concentration layer 151 and the second high-concentration layer 153 in the drain region are each formed in the recess 71.

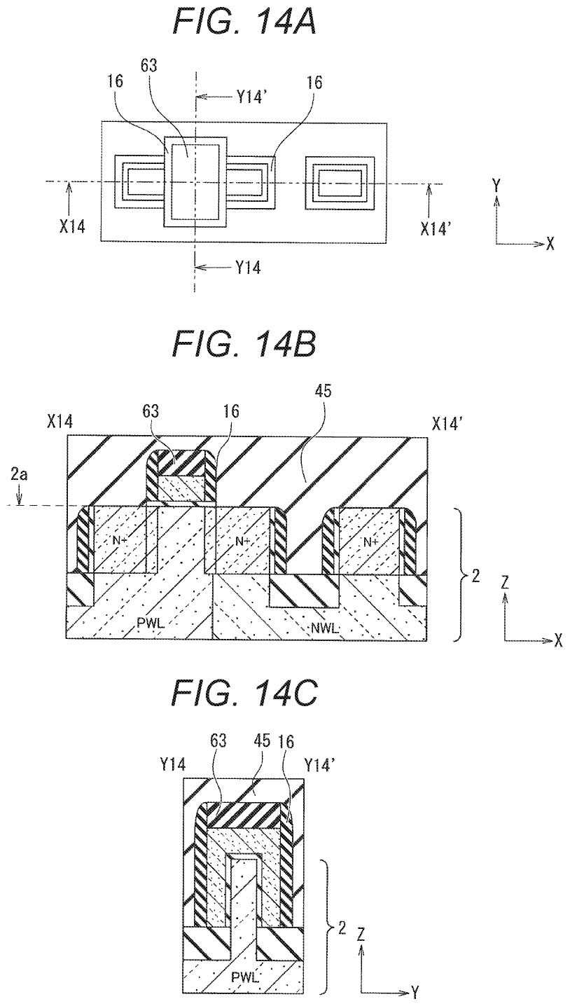

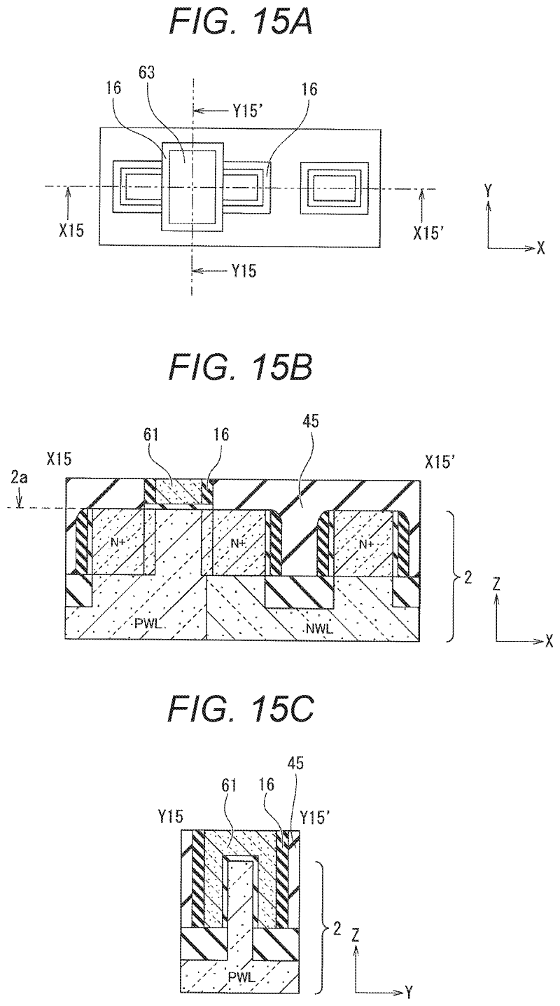

Next, as illustrated in FIGS. 14A to 14C, the manufacturing apparatus forms the interlayer insulating film 45 on the semiconductor substrate 2 by using the CVD method. Next, the manufacturing apparatus performs CMP processing on the surface of the interlayer insulating film 45, thereby flattening the surface of the interlayer insulating film 45 and removing the SiN film 63. With this process, as illustrated in FIGS. 15A to 15C, the manufacturing apparatus exposes the surface of the polysilicon film 61 from the interlayer insulating film 45. In this CMP process, since the surface of the SiN film 63 before grinding is flat and has no step, the SiN film 63 can be ground uniformly. As a result, it is possible to prevent the SiN film 63 from remaining and to prevent generation of a step or inclination on the surface of the interlayer insulating film 45 or the surface of the polysilicon film 61 after the CMP processing.

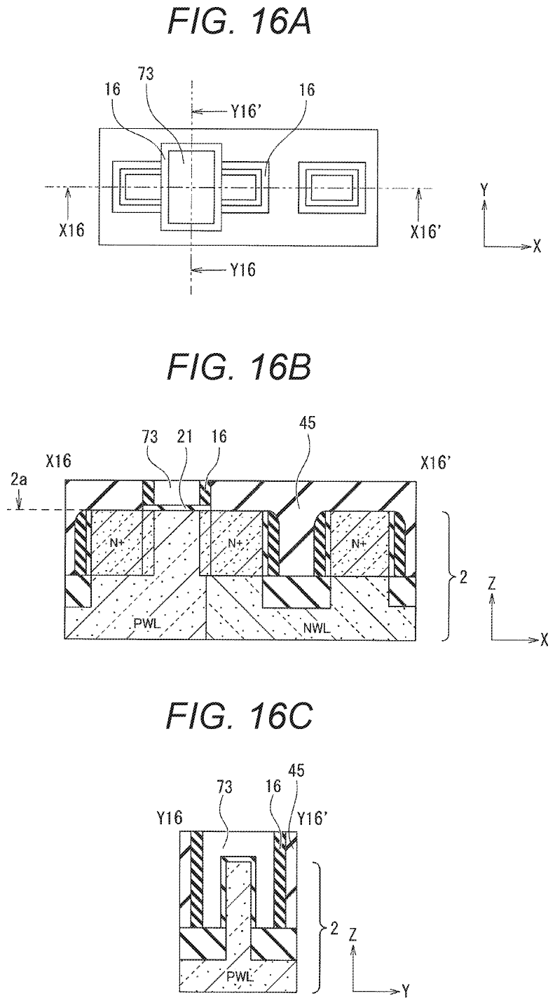

Next, the manufacturing apparatus etches and removes the polysilicon film 61. With this process, as illustrated in FIGS. 16A to 16C, the manufacturing apparatus forms the recess 73 having the gate insulating film 21 as a bottom surface.

Next, the manufacturing apparatus deposits a metal film above the semiconductor substrate 2 by a vapor deposition method or the like to fill the recess 73. Next, the manufacturing apparatus performs CMP processing on the deposited metal film, thereby removing the metal film from the region other than the recess 73. With this process, the manufacturing apparatus forms the gate electrode 31 (see FIG. 2) including metal in the recess 73. Thereafter, the manufacturing apparatus forms the source electrode 33 and the drain electrode 35. Through the above processes, the semiconductor device 1 including the MOS transistor 10A is completed.

### Effects of Embodiment

As described above, the semiconductor device 1 according to the embodiment of the present disclosure includes the semiconductor substrate 2 and the MOS transistor 10 provided on the front surface 2a side of the semiconductor substrate 2. The MOS transistor 10 includes the semiconductor region 11 in which a channel is formed, the N-type source region 13 located on one side in the X-axis direction of the semiconductor region 11, the N-type drain region 15 located on the other side in the X-axis direction, and the drain electrode 35 connected to the drain region 15. The drain region 15 includes a structure in which the first high-concentration layer 151 having a high N-type impurity concentration, the low-concentration layer 152 having a low N-type impurity concentration, and the second high-concentration layer 153 having a high N-type impurity concentration are connected in this order from the semiconductor region 11 to the drain electrode 35 side.

With this configuration, providing the low-concentration layer 152 in the drain region 15 can increase the resistance of the drain region 15, and can increase the breakdown voltage between the source and the drain. Furthermore, the N-type low-concentration layer 152 can include a part of the N-type well diffusion layer NWL. The process of forming the N-type low-concentration layer 152 can also be used in the process of forming the N-type well diffusion layer NWL. With this arrangement, the semiconductor device 1 capable of increasing the breakdown voltage of the MOS transistor 10 while suppressing an increase in the number of processes can be provided.

Furthermore, the semiconductor device 1 further includes the STI layer 40 provided at the low-concentration layer 152. With this configuration, as the thickness of the STI layer 40 is increased, the current path of the drain current in the low-concentration layer 152 can be extended in the Z-axis direction, and the resistance of the drain region 15 can be increased. Even if the thickness of the STI layer 40 is increased, the area of the MOS transistor 10 does not increase. Therefore, the breakdown voltage of the MOS transistor 10 can be increased while an increase in the element area is suppressed.

Furthermore, the drain region 15 further includes the first connection region R1 in which the first high-concentration layer 151 and the low-concentration layer 152 are connected in the Z-axis direction, and the second connection region R2 in which the low-concentration layer 152 and the second high-concentration layer 153 are connected in the Z-axis direction. With this configuration, since the low-concentration layer 152 can be arranged below the first high-concentration layer 151 and the second high-concentration layer 153, an increase in the element area can be suppressed.

Furthermore, the MOS transistor 10 includes the gate electrode 31 covering the semiconductor region 11, and the gate insulating film 21 arranged between the semiconductor region 11 and the gate electrode 31. The semiconductor region 11 includes the upper surface 11a, the first side surface 11b located on one side of the upper surface 11a in the gate width direction of the gate electrode 31, and the second side surface 11c located on the other side of the upper surface 11a in the gate width direction. The gate electrode 31 includes the first part 311 facing the upper surface 31a across the gate insulating film 21, the second part 312 facing the first side surface 11b across the gate insulating film 21, and the third part 313 facing the second side surface 11c across the gate insulating film 21. With this configuration, it is possible to realize the MOS transistor 10 having a recessed gate structure, capable of increasing a breakdown voltage while suppressing an increase in the number of processes and suppressing an increase in the element area.

### Modification Example 1

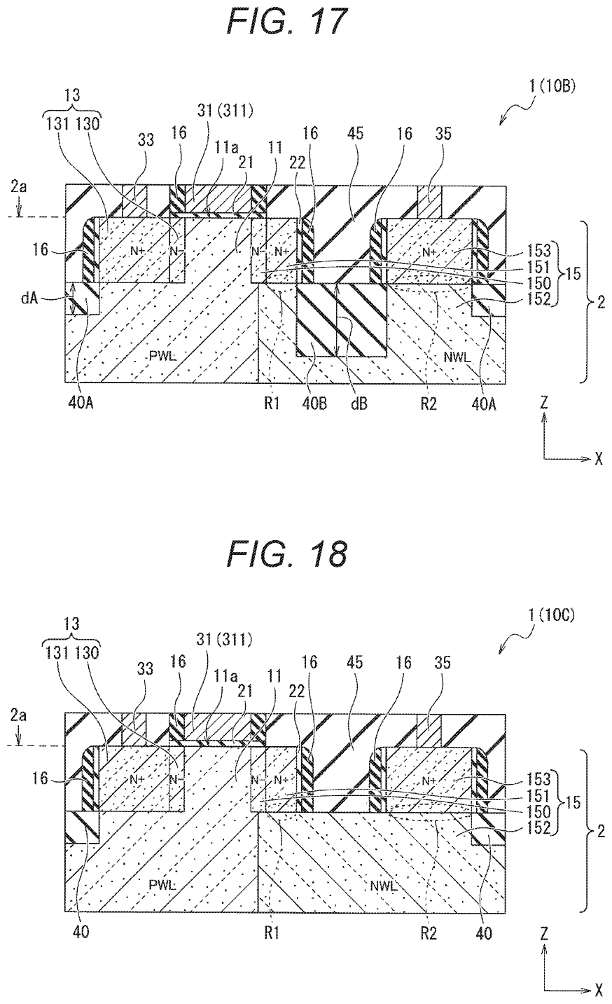

In the embodiments of the present disclosure, the thickness of the STI layer provided in the drain region of the MOS transistor and the thickness of the STI layer provided in the other region may differ from each other. FIG. 17 is a sectional view illustrating Modification Example 1 of the semiconductor device 1 according to the embodiment of the present disclosure. As illustrated in FIG. 17, in Modification Example 1 of the embodiment, the semiconductor device 1 includes the MOS transistor 10B, an STI layer 40A provided around the MOS transistor 10B, and an STI layer 40B provided in the drain region 15 (these two STI layers are an example of an “insulating layer” of the present disclosure). The STI layer 40A electrically isolates the MOS transistor 10B and other elements located around the MOS transistor 10B (not illustrated) from each other. The STI layer 40B is provided on the low-concentration layer 152 located between the first high-concentration layer 151 and the second high-concentration layer 153 in the drain region 15.

The surfaces of the STI layers 40A and 40B are located at the heights identical to each other. Furthermore, a thickness dB of the STI layer 40B is larger than a thickness dA of the STI layer.

Even with such a configuration, effects similar to those of the above-described first embodiment are exerted. Furthermore, since the thickness of the STI layer 40B is large, the current path in the low-concentration layer 152 can be further lengthened in the Z-axis direction. Therefore, the MOS transistor 10B can further increase a breakdown voltage.

### Modification Example 2

In the embodiment of the present disclosure, the STI layer may not be provided in the drain region. FIG. 18 is a sectional view illustrating Modification Example 2 of the semiconductor device 1 according to the embodiment of the present disclosure. As illustrated in FIG. 18, in Modification Example 2 of the embodiment, the semiconductor device 1 includes the MOS transistor 10C. In the MOS transistor 10C, the STI layer 40 (see FIG. 2) is not provided on the low-concentration layer 152 located between the first high-concentration layer 151 and the second high-concentration layer 153.

Even in such a configuration, the low-concentration layer 152 is arranged between the first high-concentration layer 151 and the second high-concentration layer 153. Furthermore, the low-concentration layer 152 is a part of the N-type well diffusion layer NWL. Therefore, the MOS transistor 10C can increase a breakdown voltage while suppressing an increase in the number of processes.

### Modification Example 3

In the embodiment of the present disclosure, a trench may not be provided in the drain region. FIG. 19 is a sectional view illustrating Modification Example 3 of the semiconductor device 1 according to the embodiment of the present disclosure. As illustrated in FIG. 19, in Modification Example 3 of the embodiment, the semiconductor device 1 includes the MOS transistor 10D. In the MOS transistor 10D, the STI layer 40 is not provided and the trench H3 is also not provided on the low-concentration layer 152 located between the first high-concentration layer 151 and the second high-concentration layer 153.

Even in such a configuration, the low-concentration layer 152 is arranged between the first high-concentration layer 151 and the second high-concentration layer 153. Furthermore, the low-concentration layer 152 is a part of the N-type well diffusion layer NWL. Therefore, the MOS transistor 10D can increase a breakdown voltage while suppressing an increase in the number of processes.

### Modification Example 4

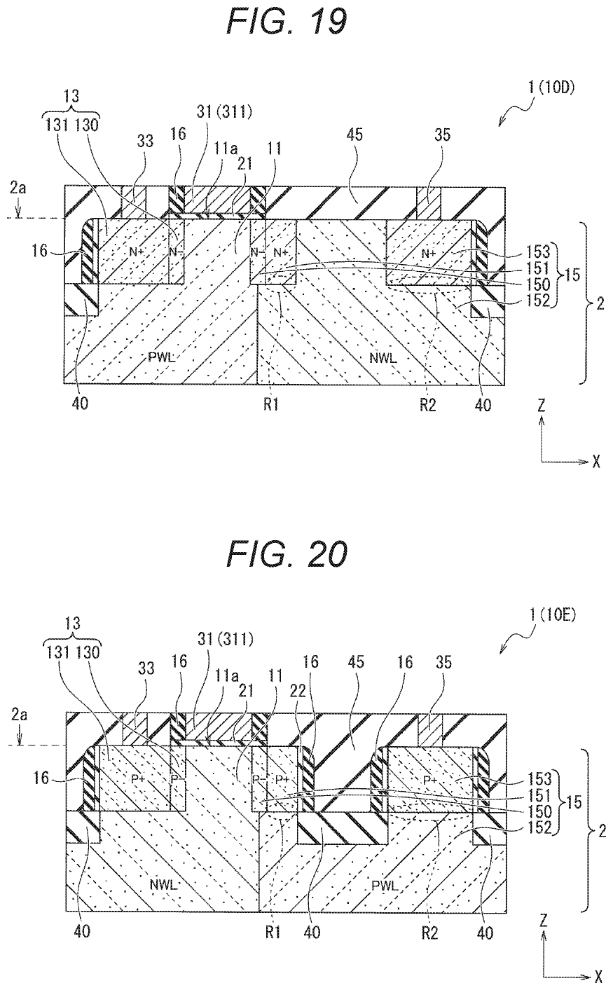

In the embodiment described above, a case where the first conductivity type is the N-type and the second conductivity type is the P-type has been described. However, the conductivity types may be selected to have the relationship opposite to the above, and the first conductivity type may be set to the P-type and the second conductivity type may be set to the N-type. FIG. 20 is a sectional view illustrating Modification Example 4 of the semiconductor device 1 according to the embodiment of the present disclosure. As illustrated in FIG. 20, in Modification Example 4 of the embodiment, the semiconductor device 1 includes the P-type MOS transistor 10E, not the N-type one. In the MOS transistor 10E, the STI layer 40 and the trench H3 are provided on a P-type low-concentration layer 152 located between a P-type first high-concentration layer 151 and a P-type second high-concentration layer 153.

Even in such a configuration, the low-concentration layer 152 is arranged between the first high-concentration layer 151 and the second high-concentration layer 153. Furthermore, the low-concentration layer 152 is a part of the P-type well diffusion layer PWL. Therefore, the MOS transistor 10E can increase a breakdown voltage while suppressing an increase in the number of processes.

### Modification Example 5

In the embodiment described above, it has been stated that the MOS transistor includes a recessed gate structure. However, in the present disclosure, the MOS transistor is not limited to that includes a recessed gate structure. In the present disclosure, the MOS transistor may be planar.

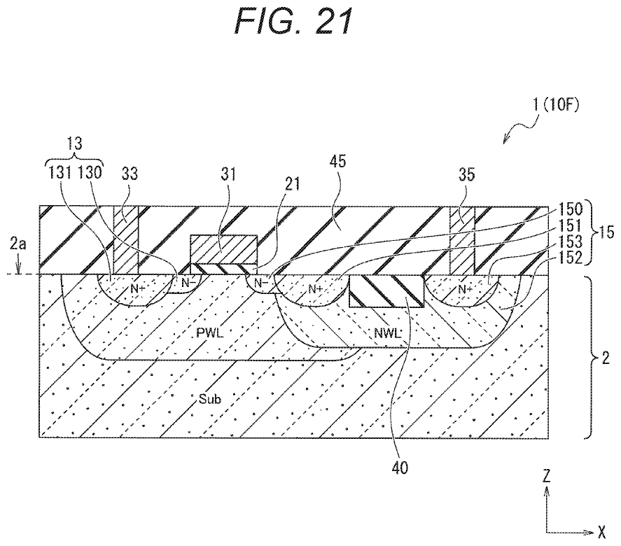

FIG. 21 is a sectional view illustrating Modification Example 5 of the semiconductor device 1 according to the embodiment of the present disclosure. As illustrated in FIG. 21, the planar MOS transistor 10F provided at the semiconductor substrate 2 is provided in Modification Example 5 of the embodiment. In the MOS transistor 10F, the gate electrode 31 is formed flat on the front surface 2a of the semiconductor substrate 2 with the gate insulating film 21 interposed therebetween.

Even in such a configuration, the low-concentration layer 152 is arranged between the first high-concentration layer 151 and the second high-concentration layer 153. Furthermore, the low-concentration layer 152 is a part of the N-type well diffusion layer NWL. Therefore, the MOS transistor 10F can increase a breakdown voltage while suppressing an increase in the number of processes.

### Other Embodiments

Although the present disclosure has been described above in the form of an embodiment and modification examples, the descriptions and drawings that constitute parts of the present disclosure are not to be understood as limiting the present disclosure. Various alternative embodiments, examples, and operable techniques will become apparent from this disclosure to those skilled in the art. The present technology obviously includes various embodiments and the like that are not described herein. At least one of various omissions, replacements, or modifications of the components can be performed without departing from the gist of the embodiment and the respective modification examples described above. Furthermore, the advantageous effects described in the present specification are merely exemplary and are not restrictive, and other advantageous effects may be produced.

Note that the present disclosure can also have the following configurations.

(1)

A semiconductor device including:

a semiconductor substrate; and

a field effect transistor provided on a first main surface side of the semiconductor substrate,

in which the field effect transistor includes

a semiconductor region in which a channel is formed,

a source region of a first conductivity type, the source region being located on one side in a gate length direction of the semiconductor region,

a drain region of the first conductivity type, the drain region being located on another side in the gate length direction, and

a drain electrode connected to the drain region, and

the drain region includes a structure in which a first high-concentration layer having a high impurity concentration of the first conductivity type, a low-concentration layer having a low impurity concentration of the first conductivity type, and a second high-concentration layer having a high impurity concentration of the first conductivity type are connected in this order from the semiconductor region to the drain electrode side.

(2)

The semiconductor device according to the above-described (1), further including a well diffusion layer of the first conductivity type provided at the semiconductor substrate,

in which the low-concentration layer is a part of the well diffusion layer.

(3)

The semiconductor device according to the above-described (1) or (2), further including an insulating isolation layer provided at the low-concentration layer.

(4)

The semiconductor device according to any one of the above-described (1) to (3), in which

the drain region further includes

a first connection region where the first high-concentration layer and the low-concentration layer are connected in a thickness direction of the semiconductor substrate, and

a second connection region where the low-concentration layer and the second high-concentration layer are connected in the thickness direction.

(5)

The semiconductor device according to any one of the above-described (1) to (4), in which the field effect transistor includes

a gate electrode covering the semiconductor region, and

a gate insulating film arranged between the semiconductor region and the gate electrode,

the semiconductor region includes

an upper surface,

a first side surface located on one side of the upper surface in a gate width direction of the gate electrode, and

a second side surface located on another side of the upper surface in the gate width direction, and

the gate electrode includes

a first part facing the upper surface across the gate insulating film,

a second part facing the first side surface across the gate insulating film, and

a third part facing the second side surface across the gate insulating film.

### REFERENCE SIGNS LIST

1 Semiconductor device
2 Semiconductor substrate
2a Front surface
10, 10A, 10B, 10C, 10D, 10E, 10F MOS transistor
11 Semiconductor region
11a Upper surface
11b First side surface
11c Second side surface
13 Source region
15 Drain region

### 16 Sidewall

16′ SiN film
21 Gate insulating film
22 Insulating film
31 Gate electrode
31a Upper surface
33 Source electrode
35 Drain electrode
40, 40A, 40B STI layer
45 Interlayer insulating film
61 Polysilicon film
63 SiN film

### 71, 73 Recess

130 Low-concentration layer
131 High-concentration layer
150 First low-concentration layer
151 First high-concentration layer
152 Low-concentration layer (Second low-concentration layer)
152 Second low-concentration layer
153 Second high-concentration layer
154 Third low-concentration layer
311 First part
312 Second part
313 Third part

### H1, H2, H3 Trench

NWL Well diffusion layer
PWL Well diffusion layer
R1 First connection region
R2 Second connection region

1. A semiconductor device comprising:
a semiconductor substrate; and
a field effect transistor provided on a first main surface side of the semiconductor substrate,
wherein the field effect transistor includes
a semiconductor region in which a channel is formed,
a source region of a first conductivity type, the source region being located on one side in a gate length direction of the semiconductor region,
a drain region of the first conductivity type, the drain region being located on another side in the gate length direction, and
a drain electrode connected to the drain region, and
the drain region includes a structure in which a first high-concentration layer having a high impurity concentration of the first conductivity type, a low-concentration layer having a low impurity concentration of the first conductivity type, and a second high-concentration layer having a high impurity concentration of the first conductivity type are connected in this order from the semiconductor region to the drain electrode side.

2. The semiconductor device according to claim 1, further comprising a well diffusion layer of the first conductivity type provided at the semiconductor substrate,
wherein the low-concentration layer is a part of the well diffusion layer.

3. The semiconductor device according to claim 1, further comprising an insulating isolation layer provided at the low-concentration layer.

4. The semiconductor device according to claim 1,
wherein the drain region further includes
a first connection region where the first high-concentration layer and the low-concentration layer are connected in a thickness direction of the semiconductor substrate, and
a second connection region where the low-concentration layer and the second high-concentration layer are connected in the thickness direction.

5. The semiconductor device according to claim 1,
wherein the field effect transistor includes
a gate electrode covering the semiconductor region, and
a gate insulating film arranged between the semiconductor region and the gate electrode,
the semiconductor region includes
an upper surface,
a first side surface located on one side of the upper surface in a gate width direction of the gate electrode, and
a second side surface located on another side of the upper surface in the gate width direction, and
the gate electrode includes
a first part facing the upper surface across the gate insulating film,
a second part facing the first side surface across the gate insulating film, and
a third part facing the second side surface across the gate insulating film.
